(19) United States
(12) Patent Application Publication
(10) Pub. No.: US 2025/0115291 A1
(43) Pub. Date: Apr. 10, 2025

(54) EARLY LIFE FAILURE DETECTION FOR RESISTANCE TO POWERPACK

(71) Applicant: Steering Solutions IP Holding Corporation, Saginaw, MI (US)

(72) Inventors: Ashish Verma, Cedar Rapids, IA (US); Julie A. Kleinau, Bay City, MI (US); David M. Williams, Millington, MI (US); Peter D. Schmitt, Farmington Hills, MI (US); Christopher J. Sommer, Swartz Creek, MI (US); Kevin L. Derry, Wheeler, MI (US)

(21) Appl. No.: 18/422,596

(22) Filed: Jan. 25, 2024

Related U.S. Application Data
(60) Provisional application No. 63/542,442, filed on Oct. 4, 2023.

(51) Int. Cl. B62D 5/04; G01R 31/00; G01R 31/66

(52) U.S. Cl. CPC B62D 5/0481; G01R 31/006; G01R 31/66

(57) ABSTRACT

A method for detecting early life failure of an electrical connection of a power harness for a steering system of a vehicle including, using a processor configured to execute instructions, obtaining a resistance measurement associated with an electrical power delivery system including the electrical connection, obtaining historical resistance data obtaining at least one limit based on at least one of the historical resistance data and a functional limit, detecting an early life failure of the electrical connection based on a comparison between the resistance measurement and the at least one limit, performing at least one action in response to detecting the early life failure.

### CROSS-REFERENCE TO RELATED APPLICATIONS

This application claims the benefit of U.S. Provisional Application No. 63/542,442, filed on Oct. 4, 2023. The entire disclosure of the application referenced above is incorporated herein by reference.

### TECHNICAL FIELD

This disclosure relates to systems and methods for monitoring state of health of connections between a power source and an electric power steering (EPS) system.

### BACKGROUND OF THE INVENTION

A vehicle, such as a car, truck, sport utility vehicle, crossover, mini-van, marine craft, aircraft, all-terrain vehicle, recreational vehicle, or other suitable forms of transportation, typically includes a steering system, such as an electronic power steering (EPS) system, a steer-by-wire (SbW) steering system, a hydraulic steering system, or other suitable steering system. The steering system of such a vehicle typically controls various aspects of vehicle steering including providing steering assist to an operator of the vehicle, controlling steerable wheels of the vehicle, and the like.

### SUMMARY OF THE INVENTION

This disclosure relates generally to determining state of health of an electrical connection in a steering system of a vehicle.

In an example, a method for detecting early life failure of an electrical connection of a power harness for a steering system of a vehicle including, using a processor configured to execute instructions, obtaining a resistance measurement associated with an electrical power delivery system including the electrical connection, obtaining historical resistance data obtaining at least one limit based on at least one of the historical resistance data and a functional limit, detecting an early life failure of the electrical connection based on a comparison between the resistance measurement and the at least one limit, performing at least one action in response to detecting the early life failure.

A method for detecting early life failure of an electrical connection of a power harness for a steering system of a vehicle includes, using a processor configured to execute instructions, obtaining, subsequent to installation of the power harness in the vehicle, a first resistance measurement associated with the electrical connection, obtaining, subsequent to the first resistance measurement, a second resistance measurement associated with the electrical connection, detecting an early life failure of the electrical connection based on at least one of a comparison between the first resistance measurement and a first resistance threshold and a comparison between the second resistance measurement and a second resistance threshold, and performing at least one action in response to detecting the early life failure.

Other aspects of the disclosed embodiments include systems configured to perform steps and functions of the described methods.

These and other aspects of the present disclosure are disclosed in the following detailed description of the embodiments, the appended claims, and the accompanying figures.

### BRIEF DESCRIPTION OF THE DRAWINGS

The disclosure is best understood from the following detailed description when read in conjunction with the accompanying drawings. It is emphasized that, according to common practice, the various features of the drawings are not to-scale. On the contrary, the dimensions of the various features are arbitrarily expanded or reduced for clarity.

FIG. 1A generally illustrates a vehicle according to the principles of the present disclosure.

FIG. 1B generally illustrates a controller according to the principles of the present disclosure.

FIG. 2 generally illustrates, schematically, an example electronic power steering (EPS) system according to the principles of the present disclosure.

FIG. 3 generally illustrates example degradation of over a lifetime of an electrical connection.

FIGS. 4A and 4B generally illustrate resistance measurements relative to upper and lower control limits.

FIG. 4C is a flow diagram generally illustrating steps of an example method for detecting early life failure according to the principles of the present disclosure.

FIG. 5 is a flow diagram generally illustrating steps of another example method for detecting early life failure according to the principles of the present disclosure

### DETAILED DESCRIPTION

The following discussion is directed to various embodiments of the disclosure. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

As described, a vehicle, such as a car, truck, sport utility vehicle, crossover, mini-van, marine craft, aircraft, all-terrain vehicle, recreational vehicle, or other suitable forms of transportation, typically includes a steering system, such as an electronic power steering (EPS) system, a steer-by-wire (SbW) steering system, a hydraulic steering system, or other suitable steering system. The steering system of such a vehicle typically controls various aspects of vehicle steering including providing steering assist to an operator of the vehicle, controlling steerable wheels of the vehicle, and the like. Although described herein with respect to vehicles, the principles of the present disclosure may also be implemented in other types of transportation or non-transportation apparatuses including steering systems.

The vehicle typically includes one or more electric machines, such as electric motors configured to control various aspects of a steering system of the vehicle. A pathway for providing power from the vehicle power source (e.g. battery, alternator, power supply) to a motor controller or one or more motors of the steering system may be provided. This pathway may include of one or many harnesses, wires, connectors, terminals, fuses, or other (e.g., non-traditional) pathways for conducting current, such as a chassis ground, busbar, through an engine block, etc. Anything that can provide a low enough impedance path (high power connection) for the energy transfer can be utilized to provide power to or from the motor controller. A high power electrical harness and connector may supply electrical power from a vehicle electrical system (e.g. battery and/or alternator) to a motor controller for one or more motors of the steering system. Over the life of the vehicle, the high power connection properties may degrade, resulting in eventual loss of ability to provide input power sufficient to deliver the desired electromechanical output power to provide the steering assist or steering angle function. This degradation is observable as an effective increase in the resistance of the power connector or harness. When attempting to deliver this electromechanical output power, the supply current draw through the increased resistance of the high power connection or harness will cause a large voltage drop between the vehicle supply and the motor controller, which may cause the total voltage at the motor controller input to be low enough to result in a “turn off” or “drop from operate state,” which may result in loss of function, such as loss of assist in an EPS system, and/or loss of angle control in an advanced driver-assistance system (ADAS) or SbW system. In some examples, even if the motor controller input does not turn off, a reduced available power may result in lower torque assist, lagging response, poor feedback, reduced angle control, and overall reduced steering performance.

In some embodiments, it is desirable to detect this degraded condition and/or to limit an electromechanical output power command based on detecting this degraded condition in order to reduce the required input power and prevent loss of function of the steering system, such as loss of assist in an EPS system, or loss of angle control in an ADAS or SbW system. While performance may be reduced, this may be preferable to alternatives, which could include a full loss of the assist or angle control function.

Some systems may implement techniques to determine degradation of the input power connection (or harness) using available signals within the existing control module and software. An example system for determining power connection degradation is described in more detail in U.S. patent application Ser. No. 17/733,434, filed on Apr. 29, 2022, the entire contents of which are incorporated herein by reference. In this example, electric power is applied to the motor phases and the response is measured. The power applied is V*I, where V and I are vector quantities of applied motor voltage and motor current, respectively. In some examples, the electric power applied is selected to produce zero motor torque. For example, for EPS systems, a sinusoidal, non-torque producing current is applied to the motor phases. For ADAS and SbW systems, a sinusoidal, non-torque producing or a torque producing current may be applied. The measurement of the response (e.g., a drop or change in voltage, such as a bridge voltage of the inverter or at an input of a control module) is indicative of degradation and state of health (SOH) of the input power connection.

In some examples, detectable degradation generally increases over time (e.g., exponentially, linearly, etc.) in a somewhat predictable manner. For example, a measurement of a representative resistance (e.g., a resistance associated with the power connector or harness as described above) generally may generally increase over time as degradation increases. However, in other examples, one or more faults, material or installation inconsistencies, etc. may interfere with the electrical connection, resulting in an increase in the initial resistance associated with the electrical connection that may lead to an early life failure of the electrical connection. As used herein, “early life failure” refers to a failure of the electrical connection significantly (e.g., 50% or more) prior to an expected or typical lifetime of the electrical connection. These early life failures may be caused by manufacturing defects, contamination, process/installation defects, etc., including, but not limited to: loose or untightened bolts or other connections; partially inserted contacts/terminals; corrosion or contamination on and/or between electrical connections; crimping/stripping faults; and wire or wire strand damage.

Early life failure detection systems and methods according to the present disclosure are configured to detect early life failures (e.g., prior to operation of the vehicle, sale of the vehicle to a user, etc., early in a lifetime of a vehicle, such as within a first 300 hours, first 100 cycles, etc.) as described below in more detail.

Further, while described with respect to steering systems, the principles of the present disclosure may be implemented in other types of vehicle or non-vehicle systems comprising a motor and actuator (e.g., a windshield wiper system, propulsion system, window controller, etc.).

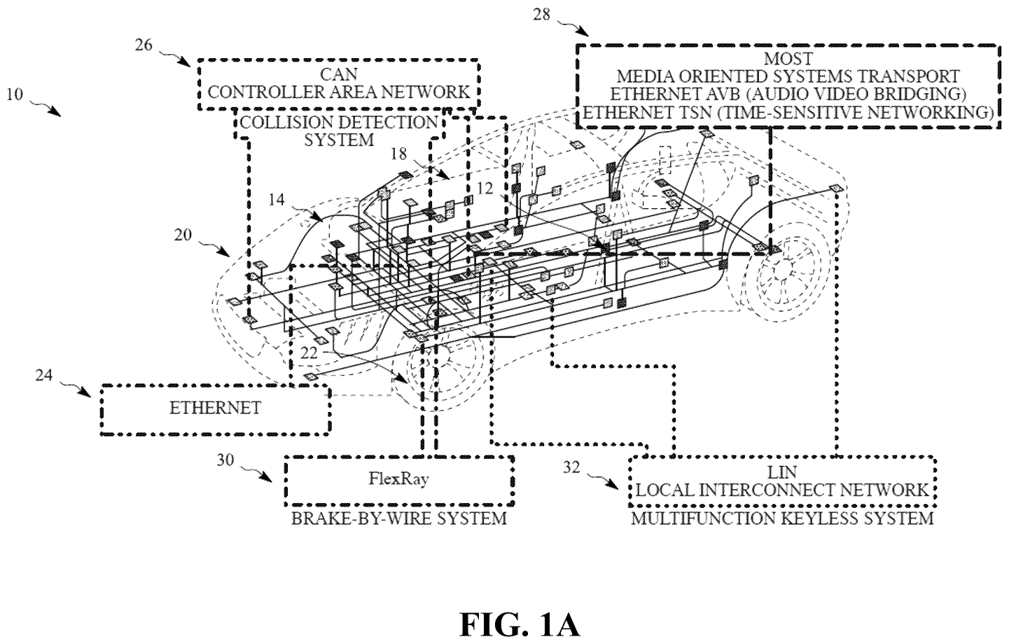

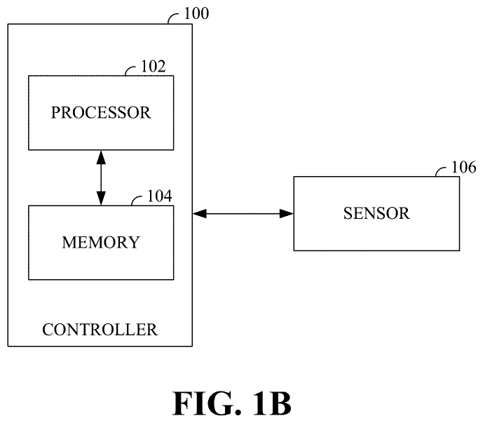

FIG. 1A generally illustrates a vehicle 10 according to the principles of the present disclosure. The vehicle 10 may include any suitable vehicle, such as a car, a truck, a sport utility vehicle, a mini-van, a crossover, any other passenger vehicle, any suitable commercial vehicle, or any other suitable vehicle. While the vehicle 10 is illustrated as a passenger vehicle having wheels and for use on roads, the principles of the present disclosure may apply to other vehicles, such as planes, boats, trains, drones, or other suitable vehicles.

The vehicle 10 includes a vehicle body 12 and a hood 14. A passenger compartment 18 is at least partially defined by the vehicle body 12. Another portion of the vehicle body 12 defines an engine compartment 20. The hood 14 may be moveably attached to a portion of the vehicle body 12, such that the hood 14 provides access to the engine compartment 20 when the hood 14 is in a first or open position and the hood 14 covers the engine compartment 20 when the hood 14 is in a second or closed position. In some embodiments, the engine compartment 20 may be disposed on rearward portion of the vehicle 10 than is generally illustrated.

The passenger compartment 18 may be disposed rearward of the engine compartment 20, but may be disposed forward of the engine compartment 20 in embodiments where the engine compartment 20 is disposed on the rearward portion of the vehicle 10. The vehicle 10 may include any suitable propulsion system including an internal combustion engine, one or more electric motors (e.g., an electric vehicle), one or more fuel cells, a hybrid (e.g., a hybrid vehicle) propulsion system comprising a combination of an internal combustion engine, one or more electric motors, and/or any other suitable propulsion system.

In some embodiments, the vehicle 10 may include a petrol or gasoline fuel engine, such as a spark ignition engine. In some embodiments, the vehicle 10 may include a diesel fuel engine, such as a compression ignition engine. The engine compartment 20 houses and/or encloses at least some components of the propulsion system of the vehicle 10. Additionally, or alternatively, propulsion controls, such as an accelerator actuator (e.g., an accelerator pedal), a brake actuator (e.g., a brake pedal), a handwheel, and other such components are disposed in the passenger compartment 18 of the vehicle 10. The propulsion controls may be actuated or controlled by an operator of the vehicle 10 and may be directly connected to corresponding components of the propulsion system, such as a throttle, a brake, a vehicle axle, a vehicle transmission, and the like, respectively. In some embodiments, the propulsion controls may communicate signals to a vehicle computer (e.g., drive by wire) which in turn may control the corresponding propulsion component of the propulsion system. As such, in some embodiments, the vehicle 10 may be an autonomous vehicle.

In some embodiments, the vehicle 10 includes a transmission in communication with a crankshaft via a flywheel or clutch or fluid coupling. In some embodiments, the transmission includes a manual transmission. In some embodiments, the transmission includes an automatic transmission. The vehicle 10 may include one or more pistons, in the case of an internal combustion engine or a hybrid vehicle, which cooperatively operate with the crankshaft to generate force, which is translated through the transmission to one or more axles, which turns wheels 22. When the vehicle 10 includes one or more electric motors, a vehicle battery, and/or fuel cell provides energy to the electric motors to turn the wheels 22.

The vehicle 10 may include automatic vehicle propulsion systems, such as a cruise control, an adaptive cruise control, automatic braking control, other automatic vehicle propulsion systems, or a combination thereof. The vehicle 10 may be an autonomous or semi-autonomous vehicle, or other suitable type of vehicle. The vehicle 10 may include additional or fewer features than those generally illustrated and/or disclosed herein.

In some embodiments, the vehicle 10 may include an Ethernet component 24, a controller area network (CAN) bus 26, a media oriented systems transport component (MOST) 28, a FlexRay component 30 (e.g., brake-by-wire system, and the like), and a local interconnect network component (LIN) 32. The vehicle 10 may use the CAN bus 26, the MOST 28, the FlexRay Component 30, the LIN 32, other suitable networks or communication systems, or a combination thereof to communicate various information from, for example, sensors within or external to the vehicle, to, for example, various processors or controllers within or external to the vehicle. The vehicle 10 may include additional or fewer features than those generally illustrated and/or disclosed herein.

In some embodiments, although not shown, the vehicle 10 may include a steering system, such as an EPS system, a steering-by-wire steering system (e.g., which may include or communicate with one or more controllers that control components of the steering system without the use of mechanical connection between the handwheel and wheels 22 of the vehicle 10), a hydraulic steering system (e.g., which may include a magnetic actuator incorporated into a valve assembly of the hydraulic steering system), or other suitable steering system.

The steering system may include an open-loop feedback control system or mechanism, a closed-loop feedback control system or mechanism, or combination thereof. The steering system may be configured to receive various inputs, including, but not limited to, a handwheel position, an input torque, one or more roadwheel positions, vehicle speed, temperature, other suitable inputs or information, such as any signals available on a vehicle communication bus, or a combination thereof.

Additionally, or alternatively, the inputs may include a handwheel torque, a handwheel angle, a motor velocity, a vehicle speed, an estimated motor torque command, other suitable input, or a combination thereof. The steering system may be configured to provide steering function and/or control to the vehicle 10. For example, the steering system may generate an assist torque based on the various inputs. The steering system may be configured to selectively control a motor of the steering system using the assist torque to provide steering assist to the operator of the vehicle 10. The steering system of the present disclosure is configured to implement early life failure detection systems and methods as described below in more detail.

In some embodiments, the vehicle 10 may include a controller, such as controller 100, as is generally illustrated in FIG. 1B. The controller 100 may include any suitable controller, such as an electronic control unit or other suitable controller. The controller 100 may be configured to control, for example, the various functions of the steering system and/or various functions of the vehicle 10. The controller 100 may include a processor 102 and a memory 104. The processor 102 may include any suitable processor, such as those described herein. Additionally, or alternatively, the controller 100 may include any suitable number of processors, in addition to or other than the processor 102. The memory 104 may comprise a single disk or a plurality of disks (e.g., hard drives), and includes a storage management module that manages one or more partitions within the memory 104. In some embodiments, memory 104 may include flash memory, semiconductor (solid state) memory or the like. The memory 104 may include Random Access Memory (RAM), a Read-Only Memory (ROM), or a combination thereof. The memory 104 may include instructions that, when executed by the processor 102, cause the processor 102 to, at least, control various aspects of the vehicle 10. Additionally, or alternatively, the memory 104 may include instructions that, when executed by the processor 102, cause the processor 102 to perform functions associated with the systems and methods described herein.

The controller 100 may receive one or more signals from various measurement devices or sensors 106 indicating sensed or measured characteristics of the vehicle 10. The sensors 106 may include any suitable sensors, measurement devices, and/or other suitable mechanisms. For example, the sensors 106 may include one or more torque sensors or devices, one or more handwheel position sensors or devices, one or more motor position sensor or devices, one or more position sensors or devices, other suitable sensors or devices, or a combination thereof. The one or more signals may indicate a handwheel torque, a handwheel angle, a motor velocity, a vehicle speed, other suitable information (e.g., controller temperature, vehicle temperature, etc.), or a combination thereof.

As used herein, “controller” may refer to a hardware module or assembly including one or more processors or microcontrollers, memory, sensors, one or more actuators, a communication interface, etc., any portions of which may be collectively referred to as “circuitry.” As described herein, respective functions and steps performed by a given controller, control circuitry, etc. may be collectively performed by multiple controllers, processors, etc. For example, a processor, processing device, controller, control circuitry, etc. “configured to perform” may refer to a single processor, processing device, controller, etc. configured to perform both A and B or may refer to a first processor, processing device, controller, etc. configured to perform A and a second processor, processing device, controller, etc. configured to perform B. For simplicity, “control circuitry configured to perform A and B” may refer to a single or multiple processors, processing devices, controllers, etc. collectively configured to perform A and B. In some examples, one or more functions may be performed remotely (e.g., relative to the vehicle), such as at a controller, processor, circuitry, etc. of a remote server, cloud computing system, and/or other remote processing system.

In some embodiments, the controller 100 may perform the methods described herein. However, the methods described herein as performed by the controller 100 are not meant to be limiting, and any type of software executed on a controller or processor can perform the methods described herein without departing from the scope of this disclosure. For example, a controller, such as a processor executing software within a computing device, can perform the methods described herein.

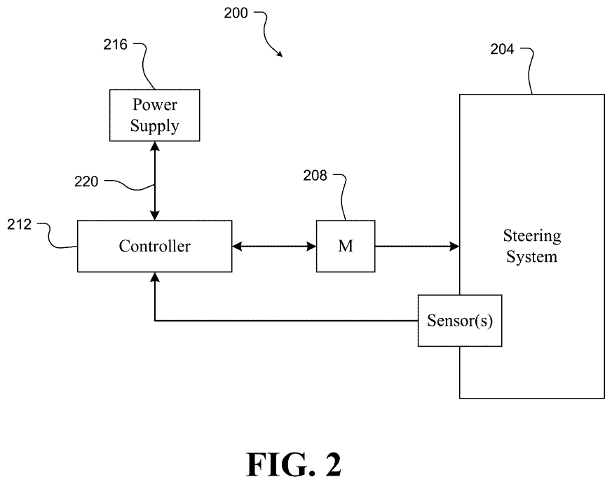

FIG. 2 generally illustrates, schematically, an example EPS system 200 according to the principles of the present disclosure. Although described with respect to an EPS system, the principles of the present disclosure may be implemented with other types of steering systems, such as SbW and ADAS systems, as well as non-steering systems.

The EPS system 200 includes a steering system 204. Details of the steering system 204 are omitted for simplicity. For example, the steering system 204 may include a rack-and-pinion type steering mechanism responsive to operator input (e.g., a steering wheel, hand wheel, etc.). In some examples, steering assist may be provided via an electric machine, such as a motor 208 (e.g., a permanent magnet synchronous motor).

The motor 208 is responsive to a controller or control circuitry 212, which receives power to control the motor 208 from a power supply 216 (which may include a battery, alternator, etc.) via a wiring harness 220. Although described herein as using the wiring harness 220, the principles of the present disclosure may be implemented for systems including other types of pathways between the power supply 216 and respective components as described above. In some examples, the motor 208, the controller 212, and/or other circuitry may collectively be referred to as a “powerpack.” Although shown for simplicity as a single connection between the power supply 216 and the controller 212, the wiring harness 220 may include multiple wired connections to various components of the EPS system 200, such as one or more direct connections to the motor 208. The wiring harness 220 may include one or more conductors, such as lengths of wire, bus bars, etc. In some examples, the wiring harness 220 includes one or more connectors, such as spade connectors, receptacles, plugs, lugs, wiring terminals, etc. Further, although described with respect to a single controller 212, the EPS system 200 may include a plurality of controllers, each having different connections between the controller and the power supply 216, a respective motor, etc., and various state of health indicators may be obtained (e.g., calculated, measured, etc.) in accordance with the principles of the present disclosure for electrical connections of respective controllers, motors, etc.

The controller 212 receives various measurement signals from respective sensors, including, but not limited to, one or more sensors 224 configured to generate measurement signals associated with the steering system 204, along with vehicle state information (vehicle speed, mileage, temperature, etc.) received through a vehicle communication bus. The measurement signals may include a steering angle (e.g., measured by a position sensor) and motor velocity. A motor velocity denoted w_m may be measured, calculated, or a combination thereof. For example, the motor velocity w_m may be calculated as the change of a motor position θ as measured by a position sensor over a prescribed time interval. For example, motor velocity w_m may be determined as the derivative of the motor position θ from the equation w_m=Δθ/Δt, where Δt is a sampling time and Δθ is a change in position during the sampling interval. Alternatively, motor velocity may be derived from motor position as the time rate of change of position.

The controller 212 controls the motor 208 to supply torque assist to the steering system 204 based on various inputs, measurement signals, etc. For example, the controller 212 is configured to supply corresponding voltages to the motor 208 via an inverter (not shown), which may optionally be incorporated within the controller 212, to cause the motor 208 to generate a desired torque and/or position.

The wiring harness 220 have an associated resistance (e.g., a harness resistance) representing resistance of electrical components in a path of current flow between the power supply 216 and an input to the controller 212 (including paths both to and from the controller 212). For example, the harness resistance has a harness resistance value Rₕₐᵣₙₑₛₛ, which is a sum of resistances of the wiring harness 220, vehicle ground, and one or more connectors or connections. Over time, these connections can erode and/or degrade and cause a total path resistance between the power supply 216 and the controller 212 to increase. Accordingly, degradation of the connections can be determined based on the harness resistance.

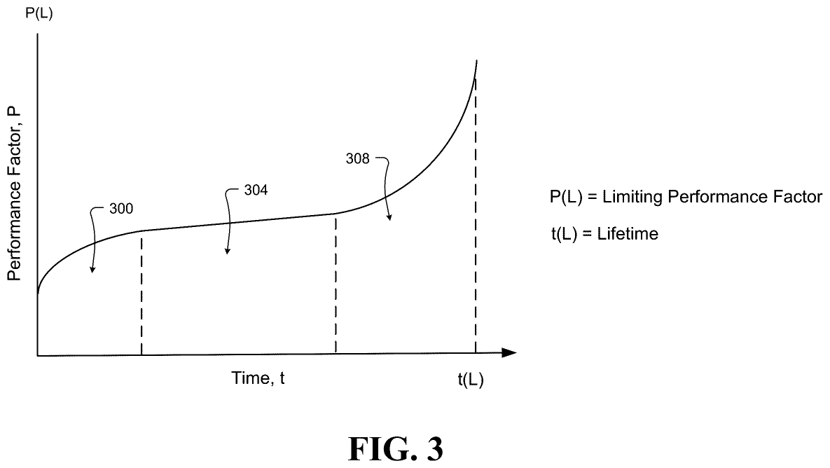

FIG. 3 illustrates example degradation of a performance factor P (e.g., for a limiting performance factor P(L)) over a lifetime t(L) of an electrical connection. Subsequent to a formation period shown at 300, performance is relatively stable (i.e., relatively flat) for a period 304 before experiencing accelerated aging and degradation of performance in a period 308. Accordingly, while resistance may generally indicate degradation, resistance alone may not accurately indicate state of health, degradation, etc. While shown generally increasing within the period 300, the performance factor P may vary (e.g., increase, decrease, etc.) within the period 300. For example, the period 300 may correspond to a “settling in” period in which various components, materials, connections, etc. stabilize subsequent to installation.

Regardless of whether the performance factor P generally increases, generally decreases, or both increases and decreases during the period 300, one or more measurements may have an expected range of values during the period 300. For example, resistance associated with the electrical connection (e.g., a resistance measured using one or more methods described herein) may have an expected range of values during the period 300, including an initial measured resistance. Accordingly, resistance measurements outside of the expected range of values may be indicative of one or more early life failures, presence of one or more conditions that may cause early life failure, etc. Early life detection systems and methods of the present disclosure are configured to detect early life failures based on various resistance measurements, including, but not limited to, an initial measured resistance. As used herein, “measurement” may refer to a direct measurement and/or a calculation, estimation, etc. of resistance based on one or more other variables.

In one example, early life detection systems and methods according to the present disclosure are configured to implement process monitoring techniques to identify features that may cause incorrect or non-optimum operation. For example, one or more control limits may be obtained based on observations and measurements of various characteristics of a given type or configuration of electrical connection. Early failures may be detected based on the control limits and one or more measurements of an electrical connection (e.g., based on deviations between the one or more measurements and corresponding control limits).

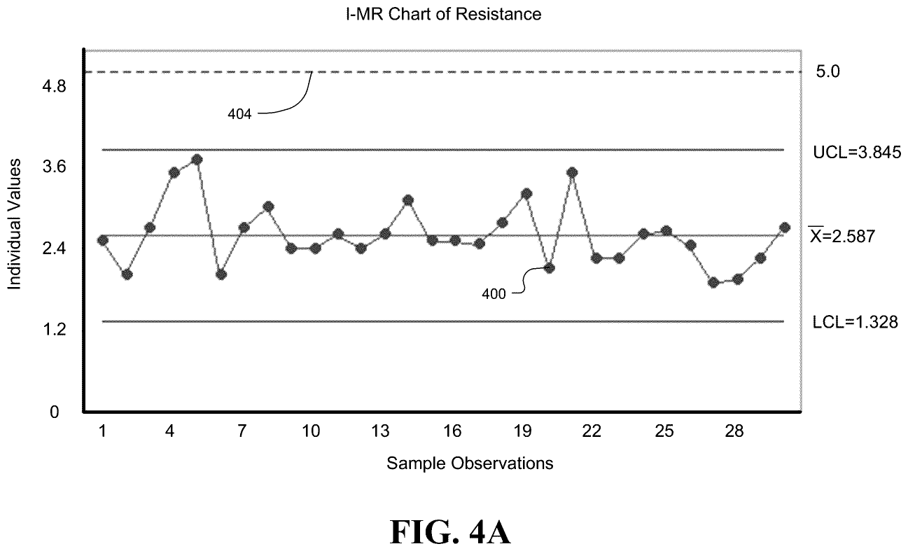

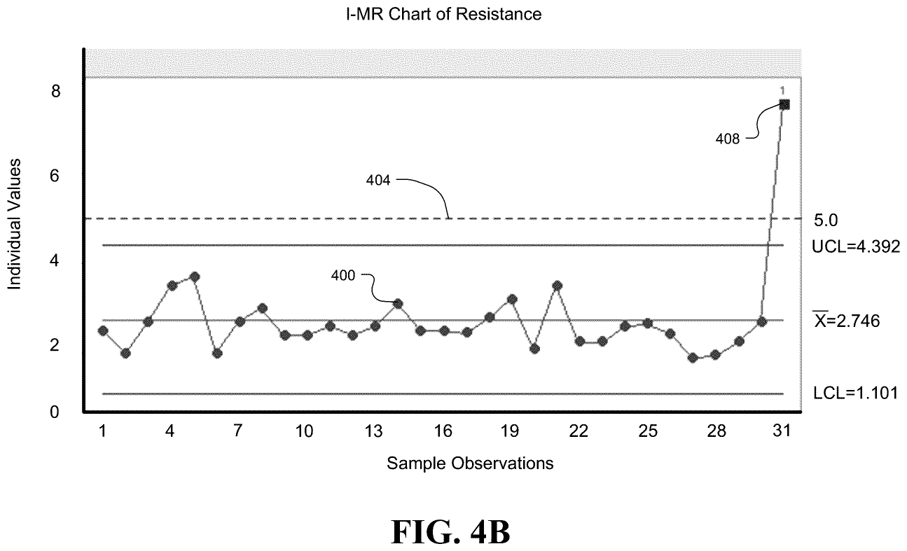

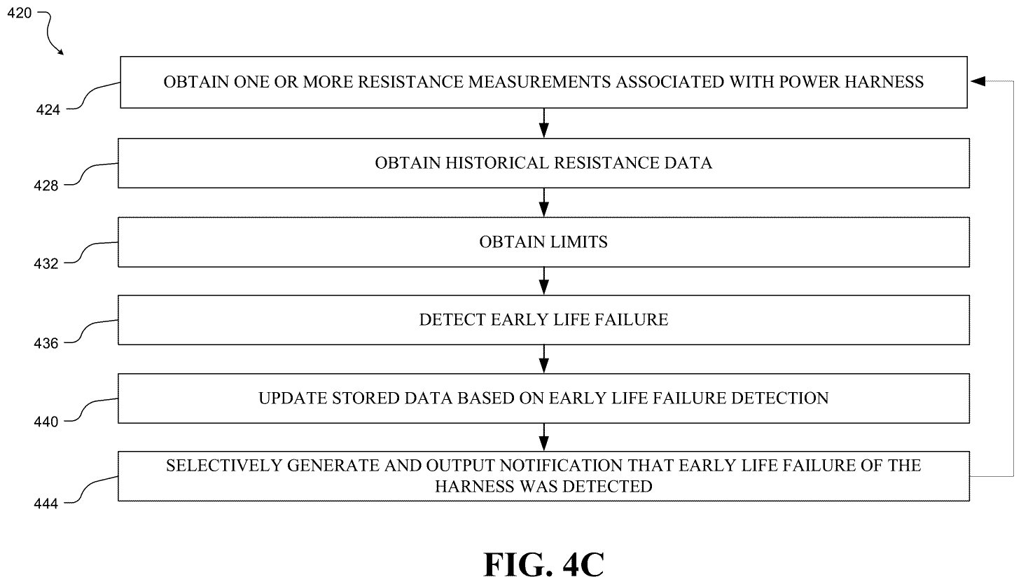

FIG. 4A illustrates an individual and moving range (I-MR) chart of example sample observations/measurements of resistance values 400 as measured (e.g., in milliohms) for respective electrical connections (e.g., electrical connections corresponding to a power harness of a steering system as described above). In this example, the measurements may correspond to resistance measurements obtained prior to installation of the power harness within a vehicle (e.g., in a manufacturing facility or environment).

In this example, for thirty observations (e.g., corresponding to thirty unique and different harnesses/electrical connection systems), the average resistance is 2.587 milliohms, an example upper control limit (UCL) is 3.845 milliohms, and an example lower control limit (LCL) is 1.328 milliohms. UCL and LCL may be calculated based on the resistance values 400. For example, the UCL and the LCL may be calculated in accordance with a standard deviation of the resistance values 400. In various examples, the UCL and LCL may be offset from the average resistance by one, two, three, etc. standard deviations. Variations in the UCL and LCL may also be adjusted by items that affect resistance measurement consistency such as run to run, temperature, humidity, and/or any other factor that may affect resistance consistency. The UCL and LCL are shown relative to a maximum allowable resistance (e.g., an upper specification limit, or USL) of 5 milliohms (as shown by dashed line 404). Accordingly, as shown in FIG. 4A, for an example maximum allowable resistance each of the harnesses measured is within a tolerance range for initial resistance as defined between the UCL and the LCL.

FIG. 4B illustrates an I-MR chart of the same example sample observations/measurements of resistance values 400 as shown in FIG. 4A with an additional data point 408 (i.e., corresponding to a 31^{st} measurement/harness) outside of the range defined by the UCL and the LCL, and is above the USL shown at 404. In other words, a harness corresponding to the measured resistance value at the data point 408 can be identified as faulty (e.g., likely leading to an early life failure) based on a comparison between the data point 408 and the control limits calculated for the data set shown in FIG. 4B. In some examples, the additional data point 408 may be considered faulty if the data point 408 is greater than the USL 404. The USL may be set such that a resistance greater than the USL would have immediately impact on the system performance, set at a level indicative of common manufacturing defects for detection (e.g., a partially tightened bolt or partially inserted connector), or set at a lower than a level that would directly affect system performance with foreknowledge of how the system will age to ensure that, in a normal aging scenario, the resistance remains below a level that would functionally change performance of the system.

Process stability, include process stability of measured resistance, may be highly temperature dependent. Accordingly, the UCL and LCL may vary based on ambient temperature. Accordingly, in some examples, systems and methods according to the present disclosure may be configured to adjust the measured resistance values 400 based on temperature. In other words, the resistance values 400 may be temperature-compensated.

FIG. 4C is a flow diagram generally illustrating steps of an example method 420 for detecting early life failures in an electrical connection according to the principles of the present disclosure. The method 420 may be performed by one or more components of the systems described herein, such as one or more controllers (e.g., the controller 100), one or more processors or processing devices (e.g., the processor 102), and/or other circuitry. In an example, one or more processors are configured to execute instructions stored in memory to perform the method 420.

At 424, one or more resistance measurements associated with a harness and/or a corresponding electrical connection are obtained. For example, a resistance query may be provided to a powerpack (e.g., a motor, controller/control circuitry, etc.) or similar system (e.g., one or more components of the system 200) coupled to the harness. For example, the query is generated and transmitted by a processor or controller of a diagnostic device. The system obtains one or more resistance measurements (e.g., by supplying a current to the motor and measuring a response of the motor as described herein) and provides the resistance measurements to the diagnostic device.

At 428, historical resistance data is obtained. For example, the historical resistance data may include resistance measurements obtained for the same type of harness/electrical connection in a same manufacturing facility. The historical resistance data may be stored in memory in the diagnostic device, stored in a remote device or server, stored in a cloud computing system, etc. Further, the USL may be derived from a maximum allowable resistance that provides the required power delivery capability for the system (e.g., a functional limit). For early life setting, the USL may be reduced from the functional limit to account for the likely aging of conducting components (resulting in increased resistance). Accordingly, the USL for early life may be set lower to validate whether a system is acceptable at initial build such that, as the system ages and increases in resistance following a typical aging routine, the resistance remains below the functional limit throughout the life of the product and no reduction in performance of the steering system is observed.

At 432, one or more limits (e.g., a UCL, LCL, USL, etc.) are obtained or set (e.g., based on the historical resistance data). At 436, the method 420 (e.g., the diagnostic device) selectively detects or predicts an early life failure of the harness based on a comparison between the one or more resistance measurements and the calculated control limits. For example, the method 420 determines whether the one or more resistance measurements is outside of a range defined by the obtained UCL, LCL, USL, or combinations thereof. One or more of the resistance measurements may be indicative of an early life failure of the harness.

At 440, the method 420 updates stored data with results of the early life failure detection. For example, the stored historical data and/or data stored within the powerpack or associated EPS system may be updated with the obtained resistance values and the results of the comparison (e.g., by setting, in memory, an indicator or flag indicating that the harness pass or failed the early life failure detection).

At 444, the method 420 optionally generates and outputs a notification that the harness failed the early life failure detection. For example, the notification may be provided to the display of a diagnostic device. The notification may indicate the one or more resistance measurements that caused the early life failure to be detected, prompt a user to repeat the early life failure detection on the harness, recommend repair or other remedial actions, etc. Further, depending on the level of resistance, a count of previous historical failures which were root caused to a particular area based on similar readings, the notification can direct the operator on likely rework activities for efficient fixing of the issue (e.g., using basic machine learning algorithms).

In other examples, a system (e.g., the EPS system 200) may be configured to perform early life failure detection according to the principles of the present disclosure subsequent to installation of the power harness within a vehicle (e.g., initially upon installation of the power harness, during an early operating period of the vehicle, etc.). In an example, resistance measurements are obtained each time the vehicle is cycled (e.g., each time the vehicle is turned on, turned off, etc.). Early life failure detection techniques implemented subsequent to installation in and during operation of the vehicle may be performed in addition to or instead of the process monitoring techniques described above in FIGS. 4A-4C. Further, in some examples, the principles of the present disclosure as described in FIGS. 4A-4C may be implemented in various levels of manufacture (powerpack, powerpack and harness, powerpack and harness and battery, etc.) and/or within a vehicle in various levels of build states. Levels of allowable resistance can be defined differently at different levels of manufacture.

For example, a powerpack of a steering system (or other devices/subsystems coupled to electrical harnesses) may have one or more design constraints, such as a maximum allowable incoming resistance from a power source. The powerpack is designed to provide a desired torque output in a system defined by the same design constraints. Accordingly, early life failure detection systems and methods of the present disclosure detect whether a system including the powerpack exceeds the maximum allowable incoming resistance (e.g., one or more resistance thresholds based on the maximum allowable incoming resistance).

In one example, the early life failure detection system (e.g., as implemented by the system 200) monitors the resistance (e.g., by periodically obtaining resistance measurements of the electrical connection as described herein) of the harness and compares the resistance to a control limit (e.g., the maximum allowable resistance). In some examples, the maximum allowable resistance is significantly greater than a typical USL (e.g., 30 milliohms for a USL of 5 milliohms). Since the measured resistance and other measurements may vary during a settling in period as described above, the system may store a first flag or other indicator in response to one or more initial resistance measurements exceeding a resistance threshold corresponding to the maximum allowable resistance. In other words, an initial resistance measurement exceeding the resistance threshold may not necessarily indicate an early life failure since measured resistance may increase and/or decrease during the settling in period.

Accordingly, the system may be configured to store a second flag or indicator in response to one or more resistance measurements, obtained subsequent to a predetermined period (e.g., subsequent to a predetermined setting in time period, subsequent to a predetermined number of sample measurements, etc.), exceeding a resistance threshold. As an example, the system may be configured to compare a single resistance measurement obtained subsequent to the predetermined period to the resistance threshold. As another example, the system may be configured to compare an average of two or more resistance measurements obtained subsequent to the predetermined period to the resistance threshold.

The system may store multiple flags or indicators based on respective calculations and measurements. For example, a first indicator may be stored in response to one or more resistance measurements exceeding resistance threshold, a second indicator may be stored in response to one or more resistance measurements, obtained subsequent to a predetermined period, exceeding the resistance threshold, etc. Various indicators may be stored in response to a specific resistance measurement sample exceeding the resistance threshold (e.g., 50th resistance measurement, a 100th resistance measurement, etc.), an average resistance measurement for a predetermined time period (e.g., an average of the 1^{st} through 50th resistance measurements, an average of the 51^{st} through 100th resistance measurements, etc.). The resistance thresholds for the various indicators may be the same or different. For example, the resistance threshold may increase with time/sample number. In some examples, initial resistance testing in-vehicle (e.g., a vehicle in use) may be performed with respect to limits at various amounts of time but may also consider a rate of change compared to an expected rate of change for a settling-in in a connection system. A large divergence from the expected settling-in may be indicative of aging or settling in an unplanned and potentially unpredictable manner and flags maybe set to indicate an early life failure concern. Accordingly, the divergence can be compared to known common settling-in curves and flags may be set if the divergence exceeds a threshold.

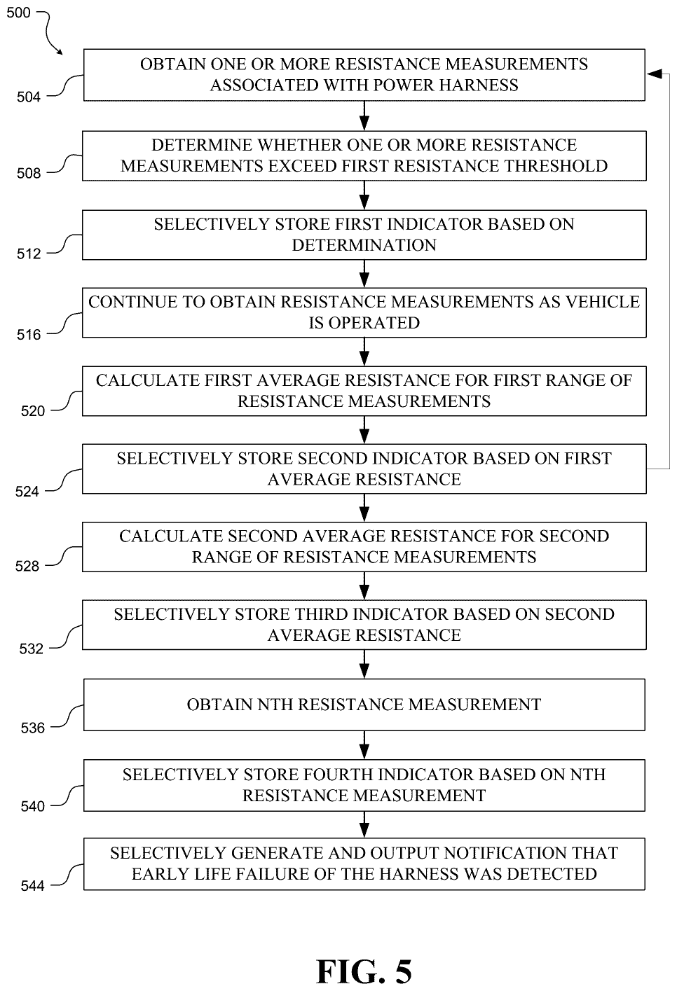

FIG. 5 is a flow diagram generally illustrating steps of an example method 500 for detecting early life failures in an electrical connection subsequent to installation in and operation of a vehicle according to the principles of the present disclosure. The method 500 may be performed by one or more components of the systems described herein, such as one or more controllers (e.g., the controller 100), one or more processors or processing devices (e.g., the processor 102), and/or other circuitry. In an example, one or more processors are configured to execute instructions stored in memory to perform the method 500.

At 504, one or more resistance measurements associated with a harness and/or a corresponding electrical connection are obtained. For example, a resistance query may be provided to a powerpack (e.g., a motor, controller/control circuitry, etc.) or similar system (e.g., one or more components of the system 200) coupled to the harness. For example, the query is generated and transmitted by a processor or controller of the powerpack (e.g., the controller 212). One or more resistance measurements (e.g., by supplying a current to the motor and measuring a response of the motor as described herein) are obtained in response to the resistance query. In some examples, the resistance query is generated automatically (e.g., periodically, conditionally, upon vehicle power on or off, etc.). Each resistance measurement may be stored as historical resistance data (e.g., in memory of the controller 212 or another component of the vehicle, in a remote server or cloud computing system, etc.) In an example, the one or more resistance measurements obtained at 504 include a first (1^{st}) resistance measurement obtained subsequent to installation of the power harness within the vehicle.

At 508, the method 500 (e.g., the controller 212) determines whether the one or more resistance measurement exceeds a first resistance threshold. The first resistance threshold corresponds to a calibratable variable (e.g., between 5 and 500 milliohms). At 512, a first indicator is stored based on the determination of whether the one or more resistance measurements exceed the first resistance threshold. For example, in response to a determination that one or more of the resistance measurements exceed the first resistance threshold, the first indicator includes data including, but not limited to, a timestamp of the one or more resistance measurements, values of the one or more resistance measurements, and an indication that the first resistance threshold was exceeded.

At 516, the method 500 continues to obtain resistance measurements (e.g., periodically, with each on/off vehicle cycle, etc.) as the vehicle is operated.

At 520, the method 500 calculates a first average resistance for a first range of resistance measurements. For example, the first average resistance corresponds to resistance measurement samples 1 through m (where m is an integer greater than 1). In an example, m=50. Although described with respect to a specific number of samples, in other examples the first range of resistance measurements may correspond to measurements taken over a predetermined time period (e.g., one month, two months, etc.).

At 524, the method 500 selectively stores a second indicator based on a determination of whether the first average resistance exceeds a second resistance threshold. The second resistance threshold may be the same as or different from the first resistance threshold. For example, the method 500 determines whether the first average resistance exceeds the second resistance threshold. The second indicator is stored based on the determination of whether the first average resistance exceeds the second resistance threshold. For example, in response to a determination that the first average resistance exceeds the second resistance threshold, the second indicator includes data including, but not limited to, a timestamp of the first average resistance, a value of the first average resistance, and an indication that the second resistance threshold was exceeded.

At 528, the method 500 calculates a second average resistance for a second range of resistance measurements. For example, the second average resistance corresponds to resistance measurement samples m through n (where n is an integer greater than m). In an example, n=100. Although described with respect to a specific number of samples, in other examples the second range of resistance measurements may correspond to measurements taken over a predetermined time period (e.g., one month, two months, etc.).

At 532, the method 500 selectively stores a third indicator based on a determination of whether the second average resistance exceeds a third resistance threshold. The third resistance threshold may be the same as or different from the first and second resistance thresholds. For example, the method 500 determines whether the second average resistance exceeds the third resistance threshold. The third indicator is stored based on the determination of whether the second average resistance exceeds the third resistance threshold. For example, in response to a determination that the second average resistance exceeds the third resistance threshold, the third indicator includes data including, but not limited to, a timestamp of the second average resistance, a value of the second average resistance, and an indication that the third resistance threshold was exceeded.

At 536, an nth resistance measurement is obtained. The nth resistance measurement may correspond to a specific number of samples (e.g., 100), a specific predetermined period, etc. For example, n may be a value selected to be subsequent to a settling in period of the vehicle and/or electrical connection.

At 540, the method 500 selectively stores a fourth indicator based on a determination of whether the nth resistance measurement exceeds a fourth resistance threshold. The fourth resistance threshold may be the same as or different from the first, second, and third resistance thresholds. For example, the method 500 determines whether the nth resistance measurement exceeds the fourth resistance threshold. The fourth indicator is stored based on the determination of whether the nth resistance measurement exceeds the fourth resistance threshold. For example, in response to a determination that the nth resistance measurement exceeds the fourth resistance threshold, the fourth indicator includes data including, but not limited to, a timestamp of the nth resistance measurement, a value of the nth resistance measurement, and an indication that the fourth resistance threshold was exceeded.

At 544, the method 500 optionally generates and outputs, based on the one or more of the first, second, third, and second indicators, a notification that an early life failure was detected. The notification may indicate the one or more resistance measurements that caused the early life failure to be detected, recommend repair or other remedial actions, etc. The notification may be provided to a driver or user, manufacturer, dealership, service facility, etc. As one example, the notification is provided to the driver or user via an in-vehicle display or interface (e.g., a display of an infotainment system or other dashboard indicator), a mobile device, etc. For example, the notification (e.g., a check engine light or other indictor) may indicate that the vehicle is in need of servicing, recommend that the driver or user schedule servicing to inspect and repair the electrical connection, replace the electrical connection, etc.

Corresponding data may be sent to a remote server or cloud computing system for remote analysis, to local diagnostic tools attached to the vehicle (e.g., OBDII readers or other diagnostic devices), etc.

In another example, control of one or more vehicle operating parameters (e.g., current provided to the motor, to the controller, etc.) may be adjusted in various conditions (e.g., when a measured temperature of the vehicle or a vehicle system is above a threshold). For example, in response to detecting the early life failure, various parameters may be controlled (e.g., current provided to the motor) to minimize additional wear on the electrical connection and avoid failure.

In one example, the method 500 may generate the notification in response to only two or more of the indicators being stored, in response to predetermined combinations of the indicators being stored, etc. For example, if the first indicator is stored but the second, third, and fourth indicators are not stored, the notification may not be generated. In other words, only the first indicator being stored may indicate that an initial resistance measurement exceeded the first resistance threshold but the resistance measurements no longer exceeded corresponding resistance thresholds subsequent to the settling in period. Conversely, if the first and second indicators are not stored but the third and fourth indicators are stored, the notification may be generated. In other words, the third and fourth indicators being stored may indicate that the measured resistance increased significantly for samples m through n, which may indicate an early life failure.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

The word “example” is used herein to mean serving as an example, instance, or illustration. Any aspect or design described herein as “example” is not necessarily to be construed as preferred or advantageous over other aspects or designs. Rather, use of the word “example” is intended to present concepts in a concrete fashion. As used in this application, the term “or” is intended to mean an inclusive “or” rather than an exclusive “or”. That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Moreover, use of the term “an implementation” or “one implementation” throughout is not intended to mean the same embodiment or implementation unless described as such.

Implementations the systems, algorithms, methods, instructions, etc., described herein can be realized in hardware, software, or any combination thereof. The hardware can include, for example, computers, intellectual property (IP) cores, application-specific integrated circuits (ASICs), programmable logic arrays, optical processors, programmable logic controllers, microcode, microcontrollers, servers, microprocessors, digital signal processors, or any other suitable circuit. In the claims, the term “processor” should be understood as encompassing any of the foregoing hardware, either singly or in combination. The terms “signal” and “data” are used interchangeably.

As used herein, the term module can include a packaged functional hardware unit designed for use with other components, a set of instructions executable by a controller (e.g., a processor executing software or firmware), processing circuitry configured to perform a particular function, and a self-contained hardware or software component that interfaces with a larger system. For example, a module can include an application specific integrated circuit (ASIC), a Field Programmable Gate Array (FPGA), a circuit, digital logic circuit, an analog circuit, a combination of discrete circuits, gates, and other types of hardware or combination thereof. In other embodiments, a module can include memory that stores instructions executable by a controller to implement a feature of the module.

Further, in one aspect, for example, systems described herein can be implemented using a general-purpose computer or general-purpose processor with a computer program that, when executed, carries out any of the respective methods, algorithms, and/or instructions described herein. In addition, or alternatively, for example, a special purpose computer/processor can be utilized which can contain other hardware for carrying out any of the methods, algorithms, or instructions described herein.

Further, all or a portion of implementations of the present disclosure can take the form of a computer program product accessible from, for example, a computer-usable or computer-readable medium. A computer-usable or computer-readable medium can be any device that can, for example, tangibly contain, store, communicate, or transport the program for use by or in connection with any processor. The medium can be, for example, an electronic, magnetic, optical, electromagnetic, or a semiconductor device. Other suitable mediums are also available.

The above-described embodiments, implementations, and aspects have been described in order to allow easy understanding of the present invention and do not limit the present invention. On the contrary, the invention is intended to cover various modifications and equivalent arrangements included within the scope of the appended claims, which scope is to be accorded the broadest interpretation so as to encompass all such modifications and equivalent structure as is permitted under the law.

What is claimed is:

1. A method for detecting early life failure of an electrical connection of a power harness for a steering system of a vehicle, the method comprising, using a processor configured to execute instructions:
obtaining a resistance measurement associated with an electrical power delivery system comprising the electrical connection;
obtaining historical resistance data;
obtaining at least one limit, wherein the at least one limit is obtained based on at least one of the historical resistance data and a functional limit;
detecting an early life failure of the electrical connection based on a comparison between the resistance measurement and the at least one limit; and
performing at least one action in response to detecting the early life failure.

2. The method of claim 1, wherein obtaining the resistance measurement includes obtaining the resistance measurement prior to installing the power harness in the vehicle.

3. The method of claim 1, wherein the at least one limit is an upper limit.

4. The method of claim 1, further comprising obtaining the resistance measurement by supplying a sinusoidal current to a motor of the steering system, measuring a response of the motor, and calculating the resistance based on the sinusoidal current and the measured response.

5. The method of claim 4, wherein the sinusoidal current is a non-torque producing current.

6. The method of claim 1, wherein the steering system is an electronic power steering (EPS) system and the electrical connection is an electrical connection between a power supply and a motor of the EPS system.

7. The method of claim 1, wherein performing the at least one action includes at least one of:
generating and displaying an indicator in response to detecting the early life failure; and
controlling at least one operating parameter of the vehicle in response to detecting the early life failure.

8. A method for detecting early life failure of an electrical connection of a power harness for a steering system of a vehicle, the method comprising, using a processor configured to execute instructions:
obtaining, subsequent to installation of the power harness in the vehicle, a first resistance measurement associated with the electrical connection;
obtaining, subsequent to the first resistance measurement, a second resistance measurement associated with the electrical connection;
detecting an early life failure of the electrical connection based on at least one of (i) a comparison between the first resistance measurement and a first resistance threshold and (ii) a comparison between the second resistance measurement and a second resistance threshold; and
performing at least one action in response to detecting the early life failure.

9. The method of claim 8, wherein obtaining the second resistance measurement includes obtaining the second resistance measurement a predetermined period or a predetermined number of measurement samples subsequent to obtaining the first resistance measurement.

10. The method of claim 9, wherein obtaining the second resistance measurement includes obtaining a first average of a first plurality of resistance measurements in a first period subsequent to obtaining the first resistance measurement.

11. The method of claim 10, further comprising:
obtaining, subsequent to the second resistance measurement, a third resistance measurement associated with the electrical connection, wherein obtaining the third resistance measurement includes obtaining a second average of a second plurality of resistance measurements in a second period subsequent to the first period; and
detecting the early life failure of the electrical connection further based on a comparison between the third resistance measurement and a third resistance threshold.

12. The method of claim 11, wherein the second period at least one of includes and overlaps with the first period.

13. The method of claim 11, wherein the second period does not overlap with the first period.

14. The method of claim 11, further comprising:
obtaining, subsequent to the third resistance measurement, a fourth resistance measurement associated with the electrical connection, wherein the fourth resistance measurement corresponds to a predetermined measurement sample number subsequent to the first resistance measurement; and
detecting the early life failure of the electrical connection further based on a comparison between the fourth resistance measurement and a fourth resistance threshold.

15. A system for detecting early life failure of an electrical connection of a power harness for a steering system of a vehicle, the system comprising;
at least one sensor configured to resistance measurements associated with the electrical connection; and
a controller configured to
obtain, subsequent to installation of the power harness in the vehicle, a first resistance measurement associated with the electrical connection,
obtain, subsequent to the first resistance measurement, a second resistance measurement associated with the electrical connection,
detect an early life failure of the electrical connection based on at least one of (i) a comparison between the first resistance measurement and a first resistance threshold and (ii) a comparison between the second resistance measurement and a second resistance threshold, and
perform at least one action in response to detecting the early life failure.

16. The system of claim 15, wherein obtaining the second resistance measurement includes obtaining the second resistance measurement a predetermined period or a predetermined number of measurement samples subsequent to obtaining the first resistance measurement.

17. The system of claim 16, wherein obtaining the second resistance measurement includes obtaining a first average of a first plurality of resistance measurements in a first period subsequent to obtaining the first resistance measurement.

18. The system of claim 17, wherein the controller is further configured to:
obtain, subsequent to the second resistance measurement, a third resistance measurement associated with the electrical connection, wherein obtaining the third resistance measurement includes obtaining a second average of a second plurality of resistance measurements in a second period subsequent to the first period; and
detect the early life failure of the electrical connection further based on a comparison between the third resistance measurement and a third resistance threshold.

19. The system of claim 18, wherein the second period at least one of includes and overlaps with the first period.

20. The system of claim 18, wherein the controller is further configured to:
obtain, subsequent to the third resistance measurement, a fourth resistance measurement associated with the electrical connection, wherein the fourth resistance measurement corresponds to a predetermined measurement sample number subsequent to the first resistance measurement; and
detect the early life failure of the electrical connection further based on a comparison between the fourth resistance measurement and a fourth resistance threshold.
